(19) United States
(12) Patent Application Publication
(10) Pub. No.: US 2019/0214427 A1
(43) Pub. Date: Jul. 11, 2019

(54) IMAGE SENSOR INCLUDING PIXEL ELECTRODES, CONTROL ELECTRODE, PHOTOELECTRIC CONVERSION FILM, TRANSPARENT ELECTRODE, AND CONNECTOR

(71) Applicant: Panasonic Intellectual Property Management Co., Ltd., Osaka (JP)

(72) Inventors: KATSUYA NOZAWA, Osaka (JP); YASUNORI INOUE, Osaka (JP)

(21) Appl. No.: 16/216,203

(22) Filed: Dec. 11, 2018

(30) Foreign Application Priority Data
Jan. 10, 2018 (JP) 2018-002198

(51) Int. Cl. H01L 27/146; H04N 5/374

(52) U.S. Cl. CPC H01L 27/14643; H01L 27/14603; H04N 5/374; H01L 27/14612; H01L 27/14636

(57) ABSTRACT

An image sensor includes: a substrate; pixel electrodes disposed on the substrate; a control electrode disposed on the substrate; a photoelectric conversion film disposed on the pixel electrodes; a transparent electrode disposed on the photoelectric conversion film; and a connector that is made of a metal or a metal nitride and electrically connects the control electrode to the transparent electrode. The control electrode is configured to be connected to a circuit that applies a voltage to the photoelectric conversion film. The transparent electrode is made of a semiconductor, and the control electrode is made of a metal or a metal nitride. The connector includes a first region in contact with the transparent electrode and a second region in contact with the control electrode. The area of the first region is larger than the area of the second region.

### BACKGROUND

### 1. Technical Field

The present disclosure relates to an image sensor.

### 2. Description of the Related Art

An image sensor includes a plurality of pixels arranged one- or two-dimensionally and each including a photo detection element that generates an electric signal according to the amount of incident light. One type of image sensor is a stacked image sensor including, as pixels, photo detection elements each having a structure including a pixel electrode, a photoelectric conversion film, and a transparent electrode that are sequentially stacked on a substrate. Examples of the stacked image sensor are disclosed in Japanese Unexamined Patent Application Publications No. 2014-60315 and No. 2015-12239.

The photo detection elements of the stacked image sensor are connected to a signal detection circuit through the pixel electrodes and connected to a voltage control circuit through the transparent electrode. The signal detection circuit detects electric signals generated when light is incident on the photo detection elements.

To allow the signal detection circuit to correctly detect the electric signals generated in the photo detection elements, the voltage control circuit controls a voltage applied to the photoelectric conversion film such that the voltage falls within a prescribed range. When a current flows from the pixel electrodes, the voltage control circuit applies the same amount of current to the transparent electrode to prevent electrification of the photo detection elements. Examples of the voltage control circuit include a constant voltage source, a variable voltage source, and a grounding conductor.

As disclosed in Japanese Patent No. 6202512, in some photoelectric conversion films, their sensitivity varies greatly depending on the voltage applied to the photoelectric conversion films, and the sensitivity can be reduced to substantially 0. In some stacked image sensors, this property is utilized to allow the photoelectric conversion film to function as an electronic shutter by changing the potential of the transparent electrode.

In a photoelectric conversion film disclosed in S. Machida et al., “A 2.1 Mpixel Organic-Film Stacked RGB-IR Image Sensor with Electrically Controllable IR Sensitivity,” ISSCC, pp. 78-79, 2017, the optical spectrum of the photoelectric conversion film, i.e., its spectral sensitivity characteristics, can be changed greatly by controlling the voltage applied to the photoelectric conversion film. In some stacked image sensors, this property is utilized. Specifically, by changing the potential of the transparent electrode, the spectral sensitivity characteristics of the photoelectric conversion film can be selected from at least two different types of spectral sensitivity characteristics.

In these image sensors, the voltage control circuit activates the electronic shutter or the function of changing the spectral sensitivity characteristics by changing the potential of the transparent electrode over time.

The transparent electrode is used to connect the photo detection elements to the voltage control circuit. The transparent electrode has optical transparency in the target detection wavelength range so as not to impede light transmission to the photoelectric conversion film. To prevent a wiring line connecting the transparent electrode to the voltage control circuit from impeding light transmission, the transparent electrode has a structure extending across a plurality of pixels and is connected to a metallic wiring line at an end portion in which no pixels are present, and the metallic wiring line connects the transparent electrode to the voltage control circuit. Therefore, a portion of the transparent electrode that is located near a circumferential edge of an imaging region serves also as a conduction path from the voltage control circuit to a portion of the transparent electrode that is located above pixels in a central portion.

To allow the transparent electrode to function as a conduction path and to have optical transparency simultaneously, the transparent electrode is formed of a conductive semiconductor material having optical transparency such as indium tin oxide (ITO), aluminum-doped zinc oxide (AZO), gallium-doped zinc oxide (GZO), or IGZO.

To connect the transparent electrode to the metallic wiring line, a control electrode disposed on a substrate side is used as a connector, or a connector disposed on the side opposite to the substrate is used, as disclosed in Japanese Patent No. 6138639. However, it is necessary to use point-to-point construction in the latter method, and the latter method has problems in that a wiring step different from a semiconductor fine patterning process is necessary, that noise tends to be generated, and that the chip is not easily reduced in area. Therefore, the former method is used in most cases.

### SUMMARY

In one general aspect, the techniques disclosed here feature an image sensor including: a substrate; pixel electrodes disposed on the substrate; a control electrode disposed on the substrate; a photoelectric conversion film disposed on the pixel electrodes; a transparent electrode disposed on the photoelectric conversion film; and a connector that is made of a metal or a metal nitride and electrically connects the control electrode to the transparent electrode. The control electrode is configured to be connected to a circuit that applies a voltage to the photoelectric conversion film. The transparent electrode is made of a semiconductor, and the control electrode is made of a metal or a metal nitride. The connector includes a first region in contact with the transparent electrode and a second region in contact with the control electrode. The area of the first region is larger than the area of the second region.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a schematic diagram showing the circuit structure of an imaging device;

FIG. 2 is a schematic diagram showing a cross section of the device structure of a unit pixel cell in the imaging device;

FIG. 3A is a schematic plan view of an image sensor in an embodiment;

FIG. 3B is a schematic cross-sectional view of the image sensor taken along line IIIB-IIIB in FIG. 3A;

FIG. 4 is a schematic cross-sectional view showing another embodiment of the image sensor;

FIG. 5 is a schematic cross-sectional view showing another embodiment of the image sensor;

FIG. 6A is a schematic plan view showing another embodiment of the image sensor;

FIG. 6B is a schematic cross-sectional view of the image sensor taken along line VIB-VIB in FIG. 6A;

FIG. 7A is a schematic plan view showing another embodiment of the image sensor;

FIG. 7B is a schematic cross-sectional view of the image sensor taken along line VIIB-VIIB in FIG. 7A;

FIG. 8A is a schematic plan view showing another embodiment of the image sensor;

FIG. 8B is a schematic cross-sectional view of the image sensor taken along line VIIIB-VIIIB in FIG. 8A;

FIG. 9 is a schematic cross-sectional view showing another embodiment of the image sensor;

FIG. 10 is a schematic cross-sectional view showing another embodiment of the image sensor; and

FIG. 11 is a schematic cross-sectional view showing another embodiment of the image sensor.

### DETAILED DESCRIPTION

As described above, in the stacked image sensor, the voltage control circuit controls the potential of the transparent electrode within a prescribed range in order for the signal detection circuit to correctly detect electric signals generated in the photo detection elements. When a current flows from the pixel electrodes, a current is caused to flow between the voltage control circuit and the transparent electrode in order to prevent electrification of the photo detection elements. To achieve the electronic shutter operation or to change the spectral sensitivity characteristics of the photoelectric conversion film, the potential of the transparent electrode is changed, for example, in a short time within one frame period.

For the purpose of the control or operation described above, the lower the resistance of a voltage application path including the transparent electrode and extending between the voltage control circuit and the photoelectric conversion film, the more advantageous it is. Specifically, fluctuations in voltage are reduced, and the power consumption is reduced. In addition, the potential can be changed at higher speed.

However, no sufficient studies have been conducted to reduce the resistance of the voltage application path. Generally, when, for example, a lower resistance material is used for the transparent electrode, the resistance of the above path can be reduced. However, the materials that can be used for the transparent electrode are limited to the above-described materials such as indium tin oxide (ITO), aluminum-doped zinc oxide (AZO), gallium-doped zinc oxide (GZO), and IGZO. Even when any of these materials is selected, it is difficult to reduce the resistance value significantly.

By increasing the cross-sectional area of the wiring line between the transparent electrode and the voltage control circuit, the resistance value can be reduced. However, when, for example, the area of the control electrode is increased, the area of the integrated circuit as a whole increases.

The present disclosure includes image sensors according to the following items.

[Item 1] An image sensor according to Item 1 of the present disclosure includes:

a substrate;

pixel electrodes disposed on the substrate;

a control electrode disposed on the substrate;

a photoelectric conversion film disposed on the pixel electrodes;

a transparent electrode disposed on the photoelectric conversion film; and

a connector that is made of a metal or a metal nitride and electrically connects the control electrode to the transparent electrode.

The control electrode is configured to be connected to a circuit that applies a voltage to the photoelectric conversion film.

The transparent electrode is made of a semiconductor, and the control electrode is made of a metal or a metal nitride.

The connector includes a first region in contact with the transparent electrode and a second region in contact with the control electrode.

An area of the first region is larger than an area of the second region.

Examples of the photoelectric conversion film includes: a film of a mixture of organic donor molecules and acceptor molecules, a film of a mixture of semiconductor carbon nanotubes and acceptor molecules; and a quantum dot-containing film. The photoelectric conversion film includes a layer that mainly functions to generate electrical signals according to the amount of incident light and may further include additional layers such as an electron blocking layer and a hole blocking layer that mainly function to prevent unwanted current from flowing from the electrodes. In the present specification, unless otherwise specified, the term “photoelectric conversion film” also encompasses a film further including these additional layers.

[Item 2] In the image sensor according to Item 1,

the connector may include a first material portion made of a first material and a second material portion made of a second material having a work function different from a work function of the first material.

The first material portion may include the first region, and

the second material portion may include the second region.

[Item 3] In the image sensor according to Item 2,

a current may flow from the transparent electrode to the pixel electrodes when the image sensor is irradiated with light, and

the work function of the first material may be smaller than the work function of the second material.

[Item 4] In the image sensor according to Item 2,

a current may flow from the pixel electrodes to the transparent electrode when the image sensor is irradiated with light, and

the work function of the first material may be larger than the work function of the second material.

[Item 5] In the image sensor according to Item 1,

the connector may include a first position portion that is in contact with at least part of an outer circumference of an upper surface of the transparent electrode, and

the first position portion may include at least part of the first region.

[Item 6] In the image sensor according to Item 5,

the first position portion may partially overlap at least part of the pixel electrodes in plan view.

[Item 7] In the image sensor according to Item 5,

the upper surface of the transparent electrode may have a rectangular shape, and

the first position portion may be disposed along at least two sides of the rectangular shape.

[Item 8] In the image sensor according to Item 7,

the control electrode may be disposed along only one of the at least two sides.

[Item 9] In the image sensor according to Item 7,

the first position portion may be disposed along four sides of the rectangular shape and may be separated on one of the four sides.

[Item 10] In the image sensor according to Item 7,

the first position portion may be disposed continuously along four sides of the rectangular shape.

[Item 11] In the image sensor according to Item 10,

the connector may further include a second position portion that is connected to the first position portion and covers a side surface of the transparent electrode, and

the second position portion may further cover a side surface of the photoelectric conversion film.

[Item 12] In the image sensor according to Item 1,

the transparent electrode may cover a side surface of the photoelectric conversion film.

[Item 13] The image sensor according to Item 5 may further include

a protective film that covers the upper surface of the transparent electrode and a side surface of the transparent electrode and has an opening located above the upper surface of the transparent electrode, and

the first position portion may be in contact with the transparent electrode through the opening.

[Item 14] The image sensor according to Item 1 may further include

a protective film that covers an upper surface of the transparent electrode, a side surface of the transparent electrode, and the control electrode.

The protective film may have a first opening located above the transparent electrode and a second opening located above the control electrode.

The connector may be located on the protective film and cover the first opening and the second opening.

The connector may be in contact with the transparent electrode through the first opening.

The connector may be in contact with the control electrode through the second opening.

[Item 15] In the image sensor according to Item 1,

the photoelectric conversion film may have spectral sensitivity characteristics that vary when the voltage applied to the photoelectric conversion film is changed.

[Item 16] In the image sensor according to Item 15,

a sensitivity of the photoelectric conversion film may be reduced to zero when the voltage is applied.

[Item 17] In the image sensor according to any one of Items 1 to 12,

the circuit may include a voltage generation circuit, and

the voltage generation circuit may generate a first voltage at a first time and generate a second voltage different from the first voltage at a second time different from the first time.

In the present disclosure, all or a part of any of circuit, unit, device, part or portion, or any of functional blocks in the block diagrams may be implemented as one or more of electronic circuits including, but not limited to, a semiconductor device, a semiconductor integrated circuit (IC) or an LSI. The LSI or IC can be integrated into one chip, or also can be a combination of plural chips. For example, functional blocks other than a memory may be integrated into one chip. The name used here is LSI or IC, but it may also be called system LSI, VLSI (very large scale integration), or ULSI (ultra large scale integration) depending on the degree of integration. A Field Programmable Gate Array (FPGA) that can be programmed after manufacturing an LSI or a reconfigurable logic device that allows reconfiguration of the connection or setup of circuit cells inside the LSI can be used for the same purpose.

Further, it is also possible that all or a part of the functions or operations of the circuit, unit, device, part or portion are implemented by executing software. In such a case, the software is recorded on one or more non-transitory recording media such as a ROM, an optical disk or a hard disk drive, and when the software is executed by a processor, the software causes the processor together with peripheral devices to execute the functions specified in the software. A system or apparatus may include such one or more non-transitory recording media on which the software is recorded and a processor together with necessary hardware devices such as an interface.

Embodiments of the image sensor of the present disclosure will be described with reference to the drawings.

### (Outline of Imaging Device Including Image Sensor)

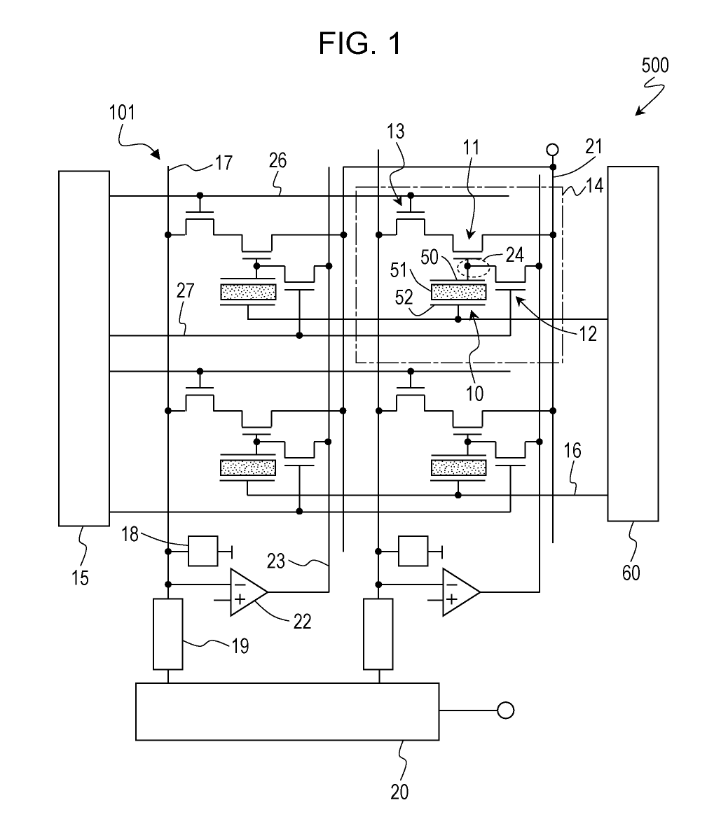

First, an outline of an imaging device that uses the image sensor of the present disclosure will be described. FIG. 1 schematically shows the circuit structure of the imaging device 500. The imaging device 500 includes: an image sensor 101 including a plurality of unit pixel cells 14; and peripheral circuits.

The plurality of unit pixel cells 14 are arranged on a semiconductor substrate two-dimensionally, i.e., in row and column directions, and form a pixel region. The image sensor 101 may be a line sensor. In this case, the plurality of unit pixel cells 14 may be arranged one-dimensionally. In the present specification, the row and column directions are the extending directions of the rows and columns. Specifically, the vertical direction is the column direction, and the horizontal direction is the row direction.

Each of the unit pixel cells 14 includes a photo detector 10, an amplification transistor 11, a reset transistor 12, and an address transistor 13. The photo detector 10 includes a pixel electrode 50 and a transparent electrode 52. The image sensor 101 includes a circuit for applying a prescribed voltage to a photoelectric conversion film 51 through the transparent electrode 52. The circuit for applying the voltage is, for example, a voltage generation circuit such as a variable power source or a constant voltage source or a reference voltage line such as a grounding conductor. The voltage applied by the voltage application circuit is referred to as control voltage. In the present embodiment, the voltage application circuit is a voltage control circuit 60. The voltage control circuit 60 may generate a constant control voltage or may generate a plurality of different control voltages. For example, the voltage control circuit 60 may generate at least two deferent control voltages or a control voltage that varies continuously in a prescribed range. The voltage control circuit 60 determines the value of the control voltage to be generated according to instructions from the operator of the imaging device 500 or instructions from another controller included in the imaging device 500 and generates the control voltage of the determined value. The voltage control circuit 60 is part of the peripheral circuits and is disposed outside a photosensitive region. Specifically, the voltage control circuit 60 may be disposed in the image sensor 101.

For example, the voltage control circuit 60 generates at least two different control voltages and applies one of the control voltages to the photoelectric conversion film 51 through the transparent electrode 52 to thereby change the spectral sensitivity characteristics of the photoelectric conversion film 51. When the spectral sensitivity characteristics are changed, the sensitivity of the photoelectric conversion film 51 to light to be detected can be reduced to zero at certain spectral sensitivity characteristics. In the imaging device 500, detection signals from the unit pixel cells 14 are read, for example, row by row. In this case, by applying a control voltage that causes the sensitivity of the photoelectric conversion film 51 to be reduced to zero from the voltage control circuit 60 to the photoelectric conversion film 51 through the transparent electrode 52, the influence of light incident during reading of the detection signals can be reduced to substantially zero. Therefore, even when the detection signals are read substantially row by row, a global shutter operation can be achieved.

As shown in FIG. 1, in the present embodiment, by applying a control voltage to the transparent electrode 52 for the unit pixel cells 14 arranged in the row direction through counter electrode signal lines 16, the voltage between the transparent electrode 52 and the pixel electrodes 50 is changed to change the spectral sensitivity characteristics of the photo detector 10. Alternatively, by applying, to the photoelectric conversion film 51 through the transparent electrode 52, a control voltage that gives spectral sensitivity characteristics that cause the light sensitivity to be reduced to zero at a prescribed timing during imaging, an electronic shutter operation is achieved. The control voltage may be applied to the pixel electrodes 50. To store holes used as signal charges in the pixel electrodes 50 by irradiating the photo detector 10 with light, the potential of the pixel electrodes 50 is set to be lower than the potential of the transparent electrode 52. In this case, since electrons move in the reverse direction, a current flows from the transparent electrode 52 to the pixel electrodes 50.

Each of the pixel electrodes 50 is connected to a gate electrode of a corresponding amplification transistor 11, and the signal charges collected by the pixel electrode 50 are stored in a charge storage node 24 located between the pixel electrode 50 and the gate electrode of the amplification transistor 11. In the present embodiment, the signal charges are holes. However, the signal charges may be electrons.

The signal charges stored in the charge storage node 24 are applied, as a voltage corresponding to the amount of the signal charges, to the gate electrode of the amplification transistor 11. The amplification transistor 11 forms a signal detection circuit and amplifies the voltage applied to the gate electrode. The address transistor 13 selectively reads the amplified voltage as a signal voltage. A source/drain electrode of the reset transistor 12 is connected to the pixel electrode 50, and the reset transistor 12 resets the signal charges stored in the charge storage node 24. In other words, the reset transistor 12 resets the potential of the gate electrode of the amplification transistor 11 and the potential of the pixel electrode 50.

To perform the above-described operation selectively on the plurality of unit pixel cells 14, the imaging device 500 includes power source lines 21, vertical signal lines 17, address signal lines 26, and reset signal lines 27. These lines are connected to the unit pixel cells 14. Specifically, the power source lines 21 are connected to the source/drain electrodes of the amplification transistors 11, and the vertical signal lines 17 are connected to the source/drain electrodes of the address transistors 13. The address signal lines 26 are connected to the gate electrodes of the address transistors 13. The reset signal lines 27 are connected to the gate electrodes of the reset transistors 12.

The peripheral circuits include a vertical scanning circuit 15, a horizontal signal reading circuit 20, a plurality of column signal processing circuits 19, a plurality of load circuits 18, and a plurality of inverting amplifiers 22. The vertical scanning circuit 15 is referred to also as a row scanning circuit. The horizontal signal reading circuit 20 is referred to also as a column scanning circuit. The column signal processing circuits 19 are referred to also as row signal storage circuits. The inverting amplifiers 22 are referred to also as feedback amplifiers.

The vertical scanning circuit 15 is connected to the address signal lines 26 and the reset signal lines 27, selects any of the rows of unit pixel cells 14, reads signal voltages from the selected unit pixel cells, and resets the potential of each of the pixel electrodes 50. The power source lines 21 used as source-follower power source lines supply a prescribed power source voltage to the unit pixel cells 14. The horizontal signal reading circuit 20 is electrically connected to the plurality of column signal processing circuits 19. The column signal processing circuits 19 are electrically connected to their respective columns of unit pixel cells 14 through the respective vertical signal lines 17. The load circuits 18 are electrically connected to the respective vertical signal lines 17. The load circuits 18 and the amplification transistors 11 form source follower circuits.

The plurality of inverting amplifiers 22 are provided for the respective columns. Negative input terminals of the inverting amplifiers 22 are connected to the respective vertical signal lines 17. Output terminals of the inverting amplifiers 22 are connected to the respective unit pixel cells 14 through feedback lines 23 provided for their respective columns.

The vertical scanning circuit 15 applies a row selection signal to the gate electrode of each address transistor 13 through its corresponding address signal line 26, and the row selection signal controls the address transistor 13 to switch it on and off. The row selection signal is applied to a row to be read, and this row is scanned and selected. Signal voltages are read from unit pixel cells 14 in the selected row through the respective vertical signal lines 17. The vertical scanning circuit 15 applies a reset signal to the gate electrode of each reset transistor 12 through a corresponding reset signal line 27, and the reset signal controls the reset transistor 12 to switch it on and off. In this manner, rows of unit pixel cells 14 to be reset are selected. The vertical signal lines 17 transmit the signal voltages read from the unit pixel cells 14 selected by the vertical scanning circuit 15 to the respective column signal processing circuits 19.

The column signal processing circuits 19 perform noise suppression signal processing typified by correlated double sampling, analog-digital conversion, etc.

The horizontal signal reading circuit 20 sequentially reads signals from the plurality of column signal processing circuits 19 and outputs the signals to a horizontal common signal line (not shown).

The inverting amplifiers 22 are connected through the feedback lines 23 to the drain electrodes of the respective reset transistors 12. Therefore, when the address transistor 13 of any of the unit pixel cells 14 is electrically continuous with the reset transistor 12 thereof, a corresponding inverting amplifier 22 receives, on its negative terminal, the output value of the address transistor 13. The inverting amplifier 22 performs a feedback operation such that the gate potential of the amplification transistor 11 is equal to a prescribed feedback voltage. In this case, the output voltage value of the inverting amplifier 22 is 0 V or a positive voltage near 0 V. The feedback voltage means the output voltage of the inverting amplifier 22.

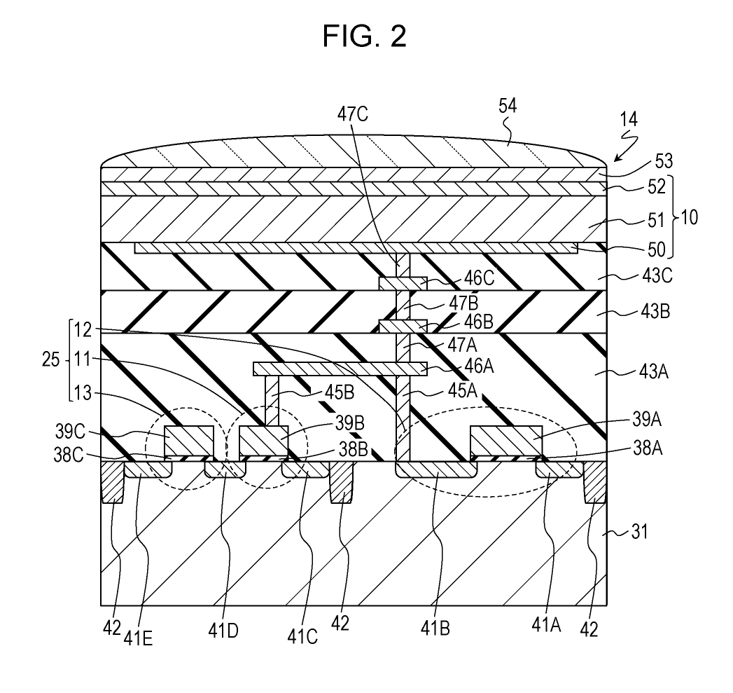

FIG. 2 is a schematic diagram showing a cross section of the device structure of a unit pixel cell 14 in the imaging device 500. The unit pixel cell 14 includes a semiconductor substrate 31, a charge detection circuit 25, and a photo detector 10. The semiconductor substrate 31 is, for example, a p-type silicon substrate. The charge detection circuit 25 detects signal charges captured by a pixel electrode 50 and outputs a signal voltage. The charge detection circuit 25 includes an amplification transistor 11, a reset transistor 12, and an address transistor 13 and is formed on the semiconductor substrate 31.

The amplification transistor 11 includes: n-type impurity regions 41C and 41D formed in the semiconductor substrate 31 and serving as drain and source electrodes, respectively; a gate insulating layer 38B located on the semiconductor substrate 31; and a gate electrode 39B located on the gate insulating layer 38B.

The reset transistor 12 includes: n-type impurity regions 41B and 41A formed in the semiconductor substrate 31 and serving as drain and source electrodes, respectively; a gate insulating layer 38A located on the semiconductor substrate 31; and a gate electrode 39A located on the gate insulating layer 38A.

The address transistor 13 includes: n-type impurity regions 41D and 41E formed in the semiconductor substrate 31 and serving as drain and source electrodes, respectively; a gate insulating layer 38C located on the semiconductor substrate 31; and a gate electrode 39C located on the gate insulating layer 38C. The n-type impurity region 41D is shared by the amplification transistor 11 and the address transistor 13. Therefore, the amplification transistor 11 and the address transistor 13 are connected in series.

In the semiconductor substrate 31, device isolation regions 42 are provided between the unit pixel cell 14 and its adjacent unit pixel cells 14 and between the amplification transistor 11 and the reset transistor 12. The device isolation regions 42 electrically isolate the unit pixel cell 14 from its adjacent unit pixel cells 14. Moreover, the device isolation regions 42 prevent leakage of the signal charges stored in the charge storage node.

Interlayer insulating layers 43A, 43B, and 43C are stacked on the surface of the semiconductor substrate 31. A contact plug 45A connected to the n-type impurity region 41B of the reset transistor 12, a contact plug 45B connected to the gate electrode 39B of the amplification transistor 11, a wiring line 46A that connects the contact plug 45A to the contact plug 45B are embedded in the interlayer insulating layer 43A. Therefore, the n-type impurity region 41B serving as the drain electrode of the reset transistor 12 is electrically connected to the gate electrode 39B of the amplification transistor 11.

The photo detector 10 is disposed on the interlayer insulating layer 43C. The photo detector 10 includes the transparent electrode 52, the photoelectric conversion film 51, and the pixel electrode 50 located closer to the semiconductor substrate 31 than the transparent electrode 52. The photoelectric conversion film 51 is sandwiched between the transparent electrode 52 and the pixel electrode 50. The structure of the photoelectric conversion film 51 will be described later in detail. The pixel electrode 50 is disposed on the interlayer insulating layer 43C. The transparent electrode 52 is formed of an electrically conductive semiconductor that is transparent to light to be detected. The transparent electrode 52 is formed of, for example, indium tin oxide (ITO), aluminum-doped zinc oxide (AZO), or gallium-doped zinc oxide (GZO). Other transparent electrically conductive semiconductors may be used. The pixel electrode 50 is formed of, for example, a metal such as aluminum or copper or polysilicon doped with impurities to impart electric conductivity.

As shown in FIG. 2, the unit pixel cell 14 further includes a color filter 53 disposed on the transparent electrode 52 of the photo detector 10. The unit pixel cell 14 may further include a microlens 54 disposed on the color filter 53.

In the present embodiment, the photoelectric conversion film 51 and the transparent electrode 52 of each unit pixel cell 14 are connected to the photoelectric conversion films 51 and the transparent electrodes 52 of adjacent unit pixel cells 14, respectively, and they form an integrated photoelectric conversion film 51 and an integrated transparent electrode 52. However, separate photoelectric conversion films 51 may be provided for the unit pixel cells 14. The pixel electrode 50 of each unit pixel cell 14 is not connected to the pixel electrodes 50 of its adjacent unit pixel cells 14 and is independent of these pixel electrodes 50.

The image sensor 101 may not detect the charges generated by photoelectric conversion but may detect changes in the capacitance of the photoelectric conversion film. An image sensor of this type and an imaging device of this type are disclosed in, for example, International Publication No. WO2017/081847. Specifically, in the photoelectric conversion film 51, hole-electron pairs may be generated according to the intensity of incident light, or the capacitance of the photoelectric conversion film 51 may change according to the intensity of incident light. By detecting the charges generated or changes in the capacitance, the light incident on the photoelectric conversion film 51 can be detected.

### (Structure of Image Sensor)

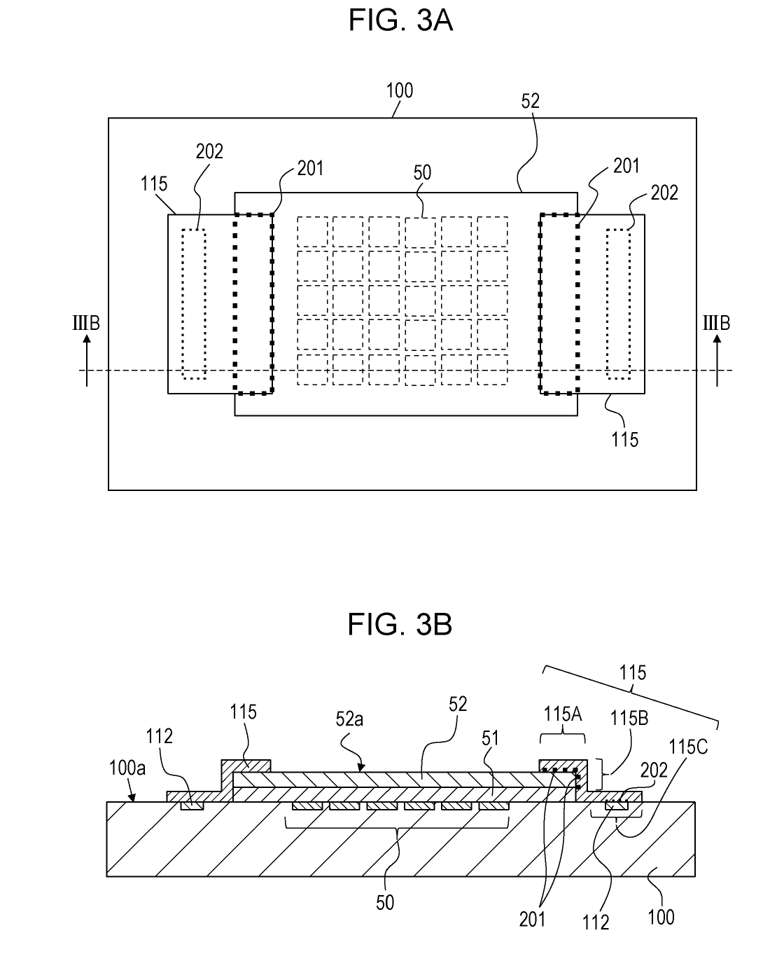

FIG. 3A is a schematic plan view of the image sensor 101, and FIG. 3B is a cross-sectional view of the image sensor 101 taken along line IIIB-IIIB in FIG. 3A. In FIGS. 3A and 3B and subsequent figures, the semiconductor substrate 31 and the interlayer insulating layers 43A, 43B, and 43C shown in FIG. 2 are collectively referred to as a substrate 100. The image sensor 101 includes the plurality of pixel electrodes 50, the photoelectric conversion film 51, and the transparent electrode 52. The image sensor 101 further includes control electrodes 112 and connectors 115. The plurality of pixel electrodes 50 and the control electrodes 112 form a circuit formed in the substrate 100. Each of the connectors 115 form part of a corresponding counter electrode signal line 16.

The plurality of pixel electrodes 50 are arranged one- or two-dimensionally and embedded in the substrate 100 such that their upper surfaces are exposed at an upper surface 100a of the substrate 100. The photoelectric conversion film 51 is disposed on the upper surface 100a of the substrate 100 so as to cover the plurality of pixel electrodes 50, and the transparent electrode 52 is disposed on the photoelectric conversion film 51. As shown in FIG. 3A, the transparent electrode 52 also covers a region outside the pixel electrodes 50 in plan view.

In the present embodiment, the image sensor 101 includes two control electrodes 112 arranged in an x-direction in plan view. The control electrodes 112 extend in a y-direction. The control electrodes 112 are embedded in the substrate 100 such that their upper surfaces are exposed at the upper surface 100a of the substrate 100. The pixel electrodes 50 are mutually electrically insulated by the interlayer insulating layers 43A, 43B, and 43C (FIG. 2) included in the substrate 100, and the pixel electrodes 50 are electrically insulated from the control electrodes 112 by the interlayer insulating layers 43A, 43B, and 43C. The control electrodes 112 are electrically connected to the voltage control circuit 60 described above.

The connectors 115 electrically connect the control electrodes 112 to the transparent electrode 52. Specifically, each connector 115 includes a first region 201 joined to the transparent electrode 52 and a second region 202 joined to a corresponding control electrode 112. The area of the first region 201 is larger than the area of the second region 202. In FIG. 3A, each first region 201 includes one region, and each second region 202 includes one region. However, one or both of the first region 201 and the second region 202 may include a plurality of regions. In this case, the area of the first region 201 and/or the area of the second region 202 is defined as the total area of the plurality of regions.

In the present embodiment, each connector 115 includes a first position portion 115A, a second position portion 115B, and a third position portion 115C. The first position portion 115A is in contact with a portion of an upper surface 52a of the transparent electrode 52 which portion is located outside the pixel electrodes 50 in plan view. The second position portion 1156 is in contact with a side surface 52c of the transparent electrode 52 and a side surface 51c of the photoelectric conversion film 51. The third position portion 115C is located on the upper surface 100a of the substrate 100 and covers one of the control electrodes 112. In the present embodiment, the first region 201 includes a section of the first position portion 115A that is in contact with the upper surface 52a of the transparent electrode 52 and a section of the second position portion 1156 that is in contact with the side surface 52c of the transparent electrode 52. As viewed in a light incident direction, the first region 201 is positioned so as not to cover the photoelectric conversion film 51 in an area in which the pixels for light detection are disposed. In other words, the first region 201 is disposed on the transparent electrode 52 in a circumferential area outside the pixel region for light detection. The second region 202 includes a section of the third position portion 115C that is in contact with one of the control electrodes 112.

The transparent electrode 52 is formed of any of the above-described materials. The control electrodes 112 are formed of a metal or a metal nitride. For example, the control electrodes 112 are formed of titanium, titanium nitride, aluminum, silicon and copper-doped aluminum, copper, tungsten, etc. or an alloy of any of these materials. Each control electrode 112 may be composed of a single layer of any of the above metals or the metal nitride or may have a layered structure including a plurality of layers.

The connectors 115 are formed of a metal or a metal nitride. The connectors 115 are formed of, for example, titanium (4.3 eV), titanium nitride (4.33 eV), aluminum (4.2 eV), silicon (4.9 eV) and copper-doped aluminum (AlSiCu), copper (4.9 eV), tungsten (4.6 eV), gold (4.5 eV), silver (4.3 eV), nickel (4.5 eV), cobalt (5 eV), or an alloy of any of these materials. The connectors 115 may be each composed of a single layer or may have a layered structure, as are the control electrodes 112. The numerical values following the names of the materials are their work functions described later.

The image sensor 101 can be produced by a conventional method for producing a semiconductor device.

Next, the reason that, in the image sensor 101, a voltage can be applied to the photoelectric conversion film through a low resistance path.

Generally, the resistance of a path is composed of: (1) a resistance component of a uniform material and (2) a resistance component at the joint surface between different materials. The first component, i.e., (1) the resistance component of a uniform material, is determined by the resistivity of the material, which is its physical property, and the shape of the material. However, (2) the resistance at the joint surface between different materials varies largely depending on the combination of the materials.

Generally, in an image sensor, its transparent electrode is formed not of a metal but of a semiconductor material in order to obtain optical transparency and low resistivity simultaneously. However, the control electrodes of the image sensor are formed of a metal or a metal nitride to achieve low resistivity. Specifically, when the transparent electrode is joined to each control electrode, different materials are joined at their interface.

In the image sensor 101 in the present embodiment, the connectors 115 that electrically connect the transparent electrode 52 to the control electrodes 112 can be disposed outside the region in which the unit pixel cells 14 are disposed. So long as the connectors 115 are disposed outside the region in which the unit pixel cells 14 are disposed, the connectors 115 may not be transparent. Therefore, in the present embodiment, the connectors 115 are formed of a metal or a metal nitride. In this case, the resistance component (1), i.e., the resistance of a uniform material, can be low.

Each connector 115 is connected to the transparent electrode 52 and a corresponding control electrode 112. At the joint between the connector 115 and the transparent electrode 52, different materials are joined. At the joint between the connector 115 and the control electrode 112, different materials are joined, but these materials are each a metal or a metal nitride and are of a similar type. Therefore, by increasing the area of the first region 201 joined to the transparent electrode 52 to increase the area of contact, the resistance component at the joint surface between the different materials, i.e., the resistance component (2), can be reduced. However, even when the area of the second region 202 joined to the control electrode 112 is small, the resistance component is not so large.

The image sensor in the present embodiment includes the connectors having the structure described above. This allows the transparent electrode to be connected to each control electrode through a low resistance path, and a voltage can be applied to the photoelectric conversion film through the transparent electrode and the low resistance path. Therefore, fluctuations in voltage are small, and images can be captured more stably. The image sensor is suitable for imaging devices for mobile devices that require low power consumption, and an imaging device with a high-speed electronic shutter or capable of changing its spectral sensitivity characteristics at high speed can be obtained.

Various modifications can be made to the image sensor 101 in the present embodiment.

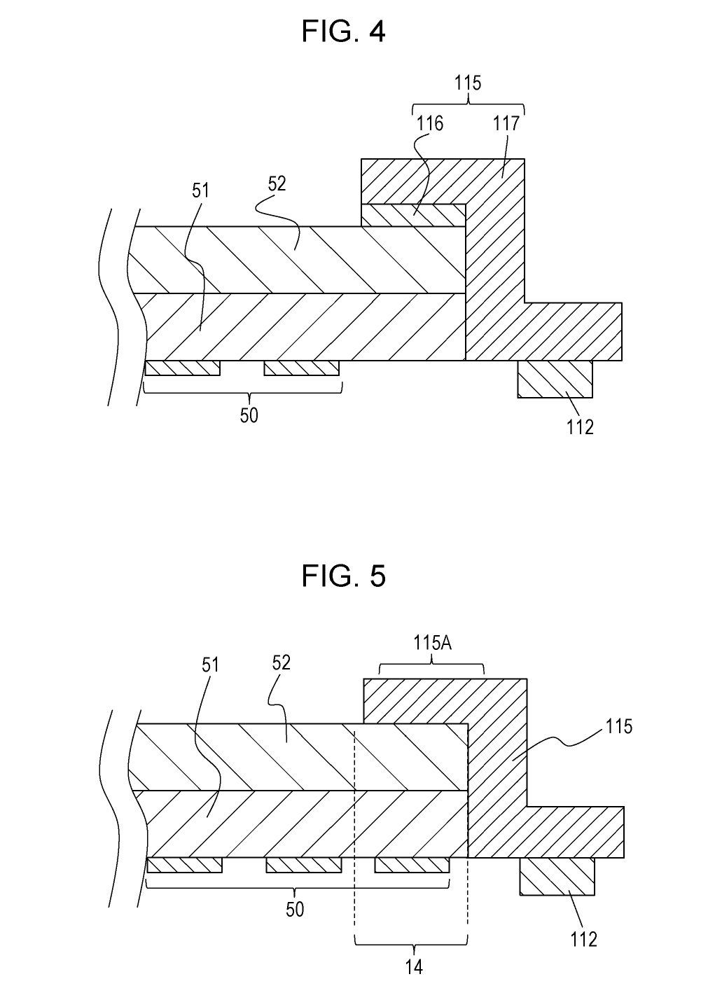

As shown in FIG. 4, each connector 115 may include two or more portions formed of materials with different work functions. Specifically, the connector 115 may include a first material portion 116 and a second material portion 117. The first material portion 116 includes the first region 201, and the second material portion 117 includes the second region 202. The resistance of the joint surface between the transparent electrode 52 and the connector 115 can be reduced for any type of charges flowing through the transparent electrode 52 by changing the materials forming the two or more portions of the connector 115 and having different work functions.

Suppose that when the image sensor 101 is irradiated with light, a current flows from the transparent electrode 52 to the pixel electrodes 50. In this case, the work function of the material forming the first material portion 116 may be smaller than the work function of the material forming the second material portion 117. The carriers flowing from the transparent electrode 52 to the control electrode 112 are electrons in this case. Therefore, the height of the Schottky barrier corresponding to the resistance at the joint surface between the transparent electrode 52 and the connector 115 can be small when the work function of the first material portion 116 in contact with the transparent electrode 52 is small.

Suppose that when the image sensor 101 is irradiated with light, a current flows from the pixel electrodes 50 to the transparent electrode 52. In this case, the work function of the material forming the first material portion 116 may be larger than the work function of the material forming the second material portion 117. The carriers flowing from the transparent electrode 52 to the control electrode 112 are holes in this case. Therefore, the resistance at the joint surface between the transparent electrode 52 and the connector 115 can be small when the work function of the first material portion 116 in contact with the transparent electrode 52 is large.

The material of the first material portion 116 and the material of the second material portion 117 can be selected from the above-described materials that can be used to form the connectors 115. The values of the work functions listed above are examples and can differ depending on the conditions of measurement, crystalline states, etc.

The first material portion 116 and the second material portion 117 may be selected from a viewpoint different from the resistance. For example, the adhesion between the material selected for the first material portion 116 and the transparent electrode 52 may be higher than the adhesion between the material selected for the second material portion 117 and the transparent electrode 52.

The arrangement and shape of the connectors 115 can be changed variously. As shown in FIG. 5, the first position portion 115A of each connector 115 may overlap at least part of the plurality of pixel electrodes 50 in plan view. The connector 115 serves as a light shielding film for a unit pixel cell 14 whose pixel electrode 50 is covered with the first position portion 115A of the connector 115, and no light is incident on this unit pixel cell 14 at all times. Therefore, this unit pixel cell 14 can be used to obtain a reference signal in a dark condition.

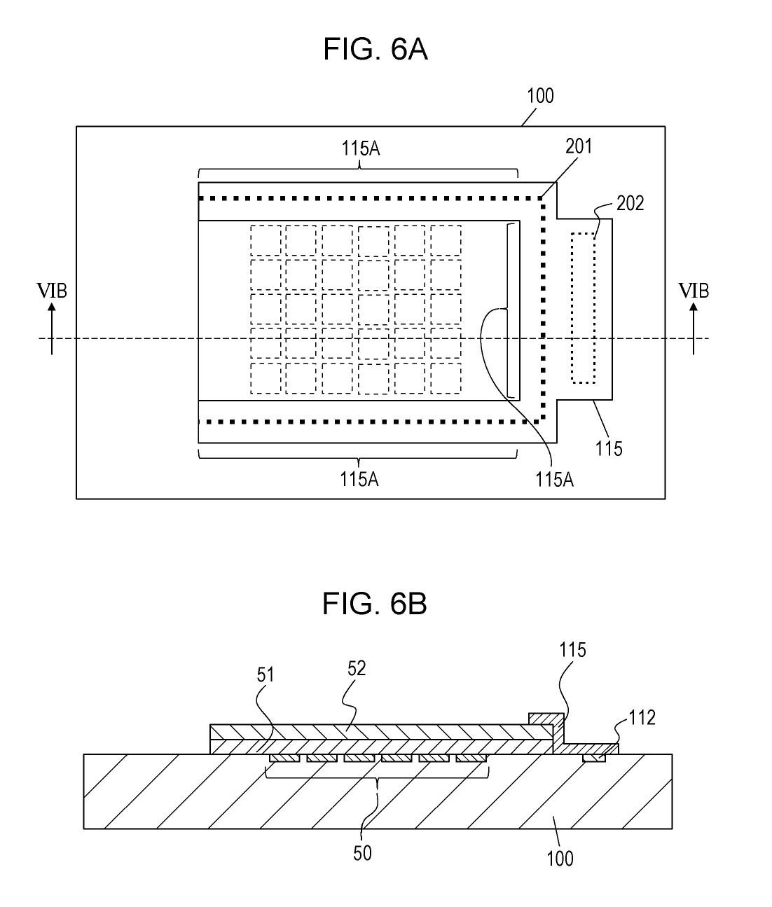

As shown in FIGS. 6A and 6B, the first position portion 115A of a connector 115 may be disposed along three sides of the upper surface 52a of the rectangular transparent electrode 52. In this case, the first region 201 is also disposed along the three sides of the rectangle so as to correspond to the first position portion 115A. In this embodiment, one control electrode 112 is disposed on the upper surface 100a of the substrate 100, and one second region 202 is provided. In this embodiment, although only one control electrode 112 is disposed, the low-resistance connector 115 is connected to the three sides of the transparent electrode 52. This can reduce delay when a voltage is applied to the transparent electrode 52.

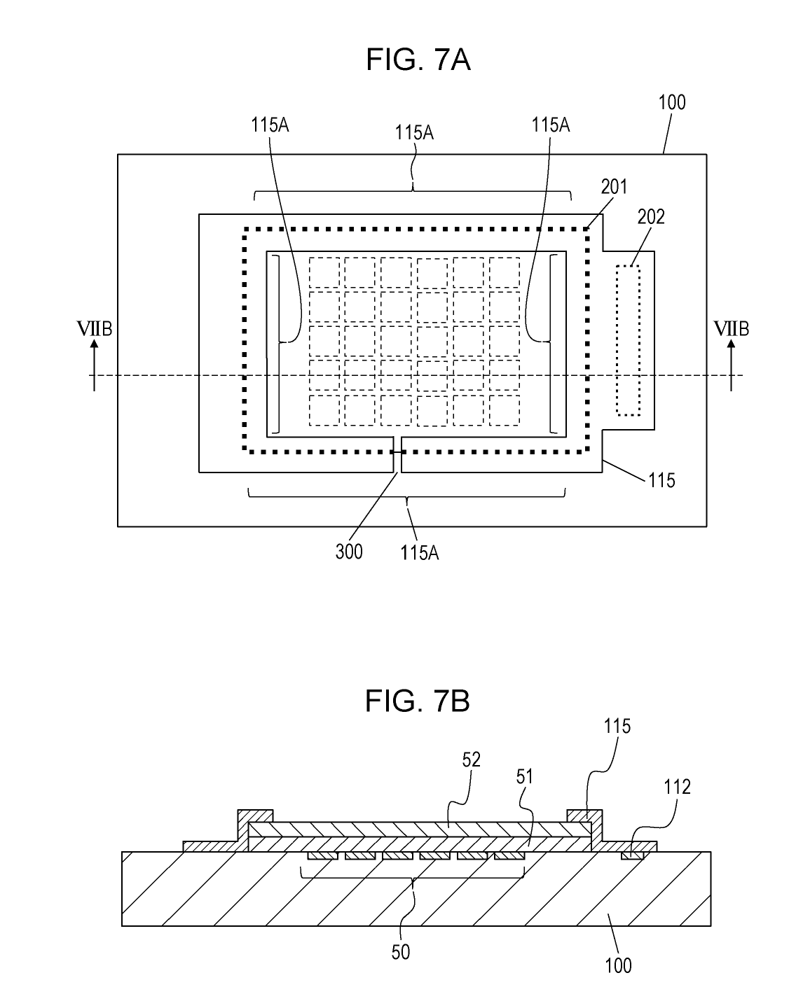

As shown in FIGS. 7A and 7B, the first position portion 115A of the connector 115 may be disposed along the four sides of the upper surface 52a of the rectangular transparent electrode 52. In this case, the first region 201 is also disposed along the four sides of the rectangle so as to correspond to the first position portion 115A. On one of the four sides, the first position portion 115A and the first region 201 are cut and separated such that a gap 300 intersecting the one of the four sides is formed between the separated edges. For example, when the connector 115 is formed using a shadow mask, the gap 300 can be used to hold a portion of the shadow mask that is disposed inside the region in which the connector 115 is formed.

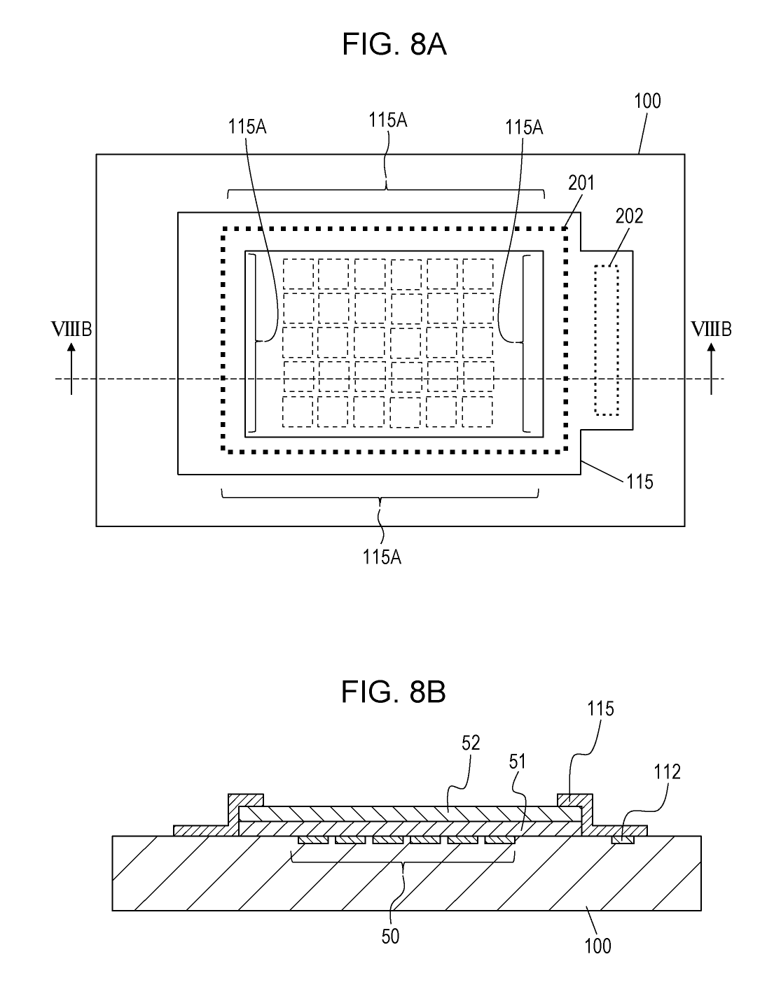

As shown in FIGS. 8A and 8B, the first position portion 115A of the connector 115 may be disposed along the four sides of the upper surface 52a of the rectangular transparent electrode 52 without the gap 300. In this case, the first position portion 115A is disposed continuously along the four sides of the rectangle. In this embodiment, the delay when a voltage is applied to the transparent electrode 52 is further reduced. Since the second position portion 115B of the connector 115 covers the entire side surfaces of the transparent electrode 52 and the entire side surfaces of the photoelectric conversion film 51, the connector 115 has the function of preventing the photoelectric conversion film 51 from being peeled from the substrate and the function of preventing the side surfaces of the photoelectric conversion film 51 from being exposed to, for example, air.

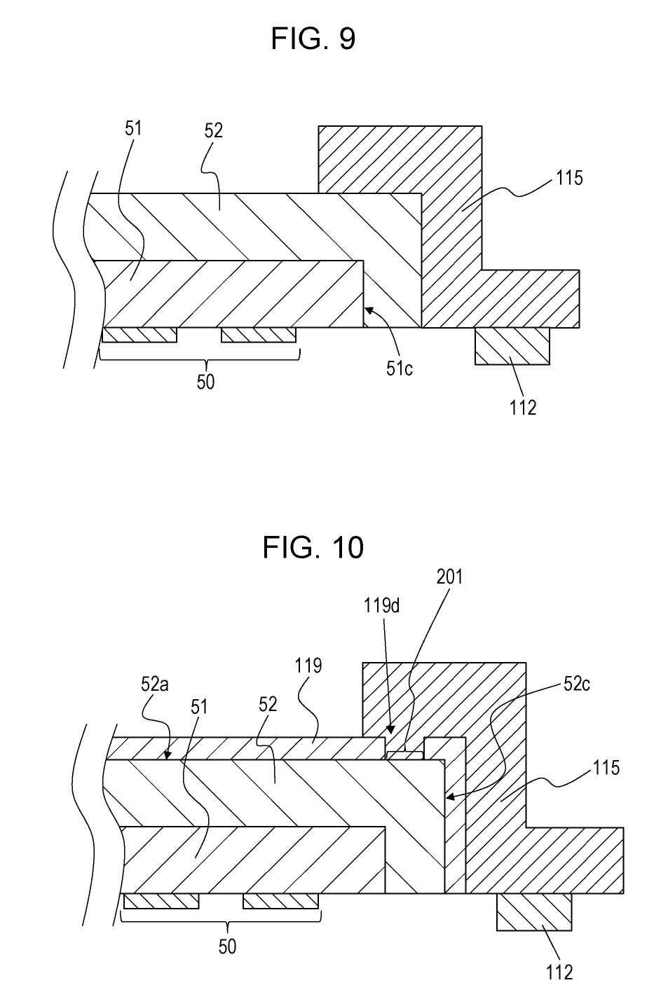

As shown in FIG. 9, the transparent electrode 52 may cover a side surface 51c of the photoelectric conversion film 51. In this embodiment, damage from the side surface 51c to the photoelectric conversion film 51 when the connector 115 is formed can be prevented.

As shown in FIG. 10, the image sensor 101 may have the structure of the embodiment shown in FIG. 9 and may further include a protective film 119 that covers the upper surface 52a of the transparent electrode 52 and its side surface 52c. The protective film 119 has a first opening 119d near the outer circumference of the transparent electrode 52, and the connector 115 is joined to the transparent electrode 52 through the first opening 119d. In this embodiment, the photoelectric conversion film 51 is prevented from being damaged by the air and an atmosphere used during a production process.

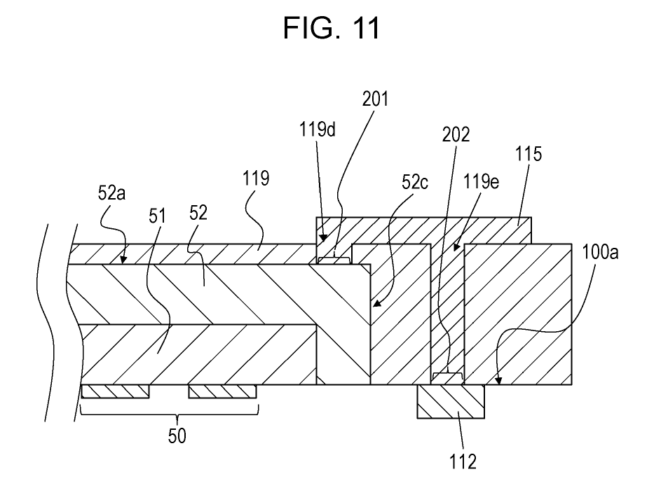

As shown in FIG. 11, the protective film 119 may be disposed also on the upper surface 100a of the substrate 100. On the upper surface 100a of the substrate 100, the protective film 119 covers the control electrode 112. For example, the level of the protective film 119 on the transparent electrode 52 may be substantially the same as its level on the upper surface 100a of the substrate 100. An upper surface 119a of the protective film 119 may be flat. To flatten the upper surface 119a of the protective film 119, a polishing method such as CMP may be used for planarization after the formation of the protective film 119. The protective film 119 may further include a second opening 119e through which part of the control electrode 112 is exposed, and the connector may be connected to the control electrode 112 through the second opening 119e.

What is claimed is:

1. An image sensor comprising:
a substrate;
pixel electrodes disposed on the substrate;
a control electrode disposed on the substrate;
a photoelectric conversion film disposed on the pixel electrodes;
a transparent electrode disposed on the photoelectric conversion film; and
a connector that is made of a metal or a metal nitride and electrically connects the control electrode to the transparent electrode, wherein
the control electrode is configured to be connected to a circuit that applies a voltage to the photoelectric conversion film,
the transparent electrode is made of a semiconductor,
the control electrode is made of a metal or a metal nitride,
the connector includes a first region in contact with the transparent electrode and a second region in contact with the control electrode, and
an area of the first region is larger than an area of the second region.

2. The image sensor according to claim 1, wherein
the connector includes a first material portion made of a first material and a second material portion made of a second material having a work function different from a work function of the first material;
the first material portion includes the first region; and
the second material portion includes the second region.

3. The image sensor according to claim 2, wherein
a current flows from the transparent electrode to the pixel electrodes when the image sensor is irradiated with light, and
the work function of the first material is smaller than the work function of the second material.

4. The image sensor according to claim 2, wherein
a current flows from the pixel electrodes to the transparent electrode when the image sensor is irradiated with light, and
the work function of the first material is larger than the work function of the second material.

5. The image sensor according to claim 1, wherein
the connector includes a first position portion that is in contact with at least part of an outer circumference of an upper surface of the transparent electrode, and
the first position portion includes at least part of the first region.

6. The image sensor according to claim 5,
wherein the first position portion partially overlaps at least part of the pixel electrodes in plan view.

7. The image sensor according to claim 5, wherein
the upper surface of the transparent electrode has a rectangular shape, and
the first position portion is disposed along at least two sides of the rectangular shape.

8. The image sensor according to claim 7,
wherein the control electrode is disposed along only one of the at least two sides.

9. The image sensor according to claim 7,
wherein the first position portion is disposed along four sides of the rectangular shape and is separated on one of the four sides.

10. The image sensor according to claim 7,
wherein the first position portion is disposed continuously along four sides of the rectangular shape.

11. The image sensor according to claim 10, wherein
the connector further includes a second position portion that is connected to the first position portion and covers a side surface of the transparent electrode, and
the second position portion further covers a side surface of the photoelectric conversion film.

12. The image sensor according to claim 1,
wherein the transparent electrode covers a side surface of the photoelectric conversion film.

13. The image sensor according to claim 5, further comprising
a protective film that covers the upper surface of the transparent electrode and a side surface of the transparent electrode and has an opening located above the upper surface of the transparent electrode, and
wherein the first position portion is in contact with the transparent electrode through the opening.

14. The image sensor according to claim 1, further comprising
a protective film that covers an upper surface of the transparent electrode, a side surface of the transparent electrode, and the control electrode, wherein
the protective film has a first opening located above the transparent electrode and a second opening located above the control electrode,
the connector is located on the protective film and covers the first opening and the second opening,
the connector is in contact with the transparent electrode through the first opening, and
the connector is in contact with the control electrode through the second opening.

15. The image sensor according to claim 1,
wherein the photoelectric conversion film has spectral sensitivity characteristics that vary when the voltage applied to the photoelectric conversion film is changed.

16. The image sensor according to claim 15,
wherein a sensitivity of the photoelectric conversion film is reduced to zero when the voltage is applied.

17. The image sensor according to claim 1, wherein
the circuit includes a voltage generation circuit, and
the voltage generation circuit generates a first voltage at a first time and generates a second voltage different from the first voltage at a second time different from the first time.
